(19) United States
(12) Patent Application Publication
(10) Pub. No.: US 2018/0328974 A1
(43) Pub. Date: Nov. 15, 2018

(54) Alternating Current Transducer

(71) Applicant: Dragan Nikolic, La Jolla, CA (US)

(72) Inventor: Dragan Nikolic, La Jolla, CA (US)

(21) Appl. No.: 15/942,320

(22) Filed: Mar. 30, 2018

Related U.S. Application Data
(60) Provisional application No. 62/503,813, filed on May 9, 2017.

(51) Int. Cl. G01R 31/08; H01F 27/24; H01F 27/28; H01F 27/40; H01F 38/20; G08B 21/18; G01R 15/20

(52) U.S. Cl. CPC G01R 31/086; H01F 27/24; H01F 27/2823; G01R 31/088; H01F 38/20; G08B 21/185; G01R 15/202; H01F 27/40

(57) ABSTRACT

An alternating current transducer. The transducer may be placed onto a powerline to detect the presence of an electric current and electromagnetic field in the powerline. An alternating current transducer including a transformer and a flexible antenna may detect and measure the electric current and detect the presence of the electromagnetic field, respectively, present in/near the powerline. The transformer and flexible antenna in electric communication with a system on a chip networking module. The networking module may transmit to a remote location, fault conditions in connection with failing to detect an electric current or electromagnetic field to be associated with a powerline.

### CROSS-REFERENCE TO RELATED APPLICATION(S)

The present application claims priority to U.S. Provisional Patent Application No. 62/503,813 filed on May 9, 2017, entitled “Alternating Current Transducer” the entire disclosure of which is incorporated by reference herein.

### BACKGROUND OF THE INVENTION

### 1. Description of Related Art

For your average household, a quick power outage or a tripped breaker may mean a slight inconvenience, but it usually would not be considered disastrous. However, in certain industries a power outage or electrical fault could mean damage to equipment, huge monetary losses, or even lost lives.

In places such as data centers, phone centrals, and medical centers a power fault could spell disaster. Not only is power critical to these systems, but usually the power system is complex and convoluted. Many times, these venues have large systems of powerlines and breakers which means more places where a fault might occur. In the event of a fault, it is crucial that the problem can be located and assessed as quickly as possible.

Based on the foregoing, there is a need in the art for a power monitoring system which can detect faults. What might be further desired is a power monitoring system which can provide the location of the fault and analysis to the cause of the fault.

### SUMMARY OF THE INVENTION

An embodiment of the present invention is provided as an alternating current transducer. In an embodiment, the alternating current transducer is comprised of a transformer having a conductive core and a series of wire wrappings, a flexible antenna, and a networking module.

In an embodiment of the present invention, the conductive core of the alternating current transducer is placed around a powerline, as to envelope the powerline. The transformer of the alternating current transducer is provided to detect and measure the electric current in the enveloped powerline and the flexible antenna is provided to detect the electromagnetic field in the powerline.

In an embodiment, the alternating current transducer is further provided with a networking module in electric communication with the transformer and flexible antenna. In an embodiment, the networking module is provided as a system on a chip. The networking module processes current signals from the transformer and detected electromagnetic field signals form the flexible antenna. In the embodiment, the networking module transmits the received signals to a monitoring system, such that faults and outages may be detected and diagnosed.

In an embodiment of the present invention, the alternating current transducer is further provided with a power supply. In an embodiment, the power supply is a battery or supercapacitor. In another embodiment, the power supply is an external power source.

In an embodiment of the present invention, the alternating current transducer is further provided with one or more indicator lights to provide a visual indication at the transducer site, of a fault condition or proper operation condition in connection with a powerline.

In an embodiment of the present invention, the alternating current transducer is further provided with a ratcheting clip. The ratcheting clip retains the alternating current transducer in a set position on the power line, such that fluctuations in the electromagnetic field detected due to reposition are mitigated.

The foregoing, and other features and advantages of the invention, will be apparent from the following, more particular description of the preferred embodiments of the invention, the accompanying drawings, and the claims.

### BRIEF DESCRIPTION OF THE DRAWINGS

For a more complete understanding of the present invention, the objects and advantages thereof, reference is now made to the ensuing descriptions taken in connection with the accompanying drawings briefly described as follows.

FIG. 1 is a simplified schematic/perspective drawing (resistor networks are not shown) illustrating current detection aspects of the fault detection system described herein.

FIG. 2 illustrates a schematic/perspective drawing of another embodiment making use of an open loop current sensor which employs a Hall-effect sensor positioned in the air gap of an open loop magnetic core.

FIG. 3 illustrates a schematic/perspective drawing of another embodiment making use of closed loop current sensor which employs a Hall-effect sensor positioned in the air gap of an open loop magnetic core.

FIG. 4 is a perspective view of the alternating current transducer, according to an embodiment of the present invention;

FIG. 5 is an exploded perspective view of the alternating current transducer, according to an embodiment of the present invention; and

FIG. 6 is an exploded perspective view of the alternating current transducer, according to an embodiment of the present invention.

### DETAILED DESCRIPTION OF EMBODIMENTS

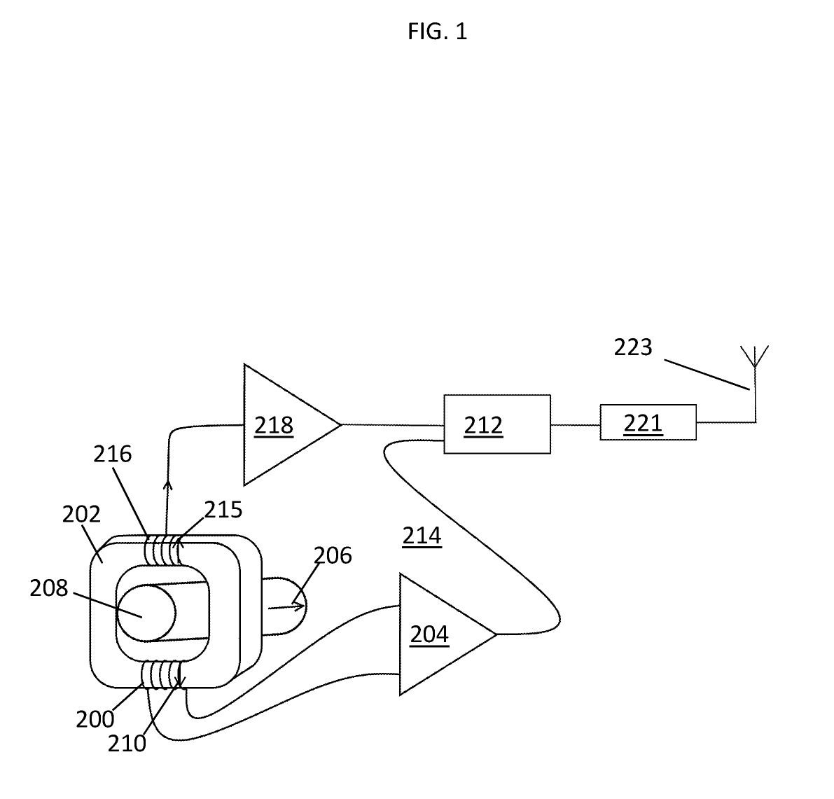

Embodiments of the present invention and their advantages may be understood by referring to FIGS. 1-6, wherein like reference numerals refer to like elements.

In fault critical environments, such as data centers, it is advantageous for a maintenance crew to be able to remotely diagnose aspects of operating conditions at the data center wherein a particular type of fault condition can be remotely ascertained without requiring the presence of the maintenance crew at the data center premises.

Fault condition aspects, of a data center or other fault-critical location, addressed herein, include the following:

a) No power to a particular server in the data center or fault-critical location;

b) No alternating current being supplied to a particular server in the data center or fault-critical location but power, is detected, on the line to the server;

c) Power on the line to a particular server in the data center is detected along with alternating current being drawn by the server.

The foregoing conditions are ascertained in connection with determining whether an electric field is detected and whether current is detected and measured.

“Detection” as used herein is contemplated as being inclusive of detection above a specified or predetermined level. Detection below such a level, may be considered as representing an instance of not detecting an electric current or electric field.

Dispatch of service personnel can be a costly undertaking. The monitoring system herein, in combination with a communication system, may greatly reduce costs in maintaining data centers or fault-critical locations by minimizing personnel dispatches so as not to result in dispatch personnel for tasks better handled by power utility personnel.

Where no power is detected, i.e., no electric field and no current, it is not necessary to dispatch data center repair personnel as the problem is an electrical service problem best handled by the power utility.

Where there is no alternating current detected as being supplied to a particular server in the data center or fault-critical location but power, is detected, on the line to the server, this represents a problem for which data center repair personnel may be dispatched to remedy the lack of power to the server. So long as a power on the line, to a particular server in the data center or fault-critical location, is detected along with alternating current being drawn by the server.

FIG. 1 is a simplified schematic/perspective drawing (resistor networks are not shown) illustrating current detection and measurement aspects of the fault detection device described herein. Coil 200 is wrapped around magnetic core 202. Each end of coil 200 feeds the input of an amplifier such as buffer 204. In connection with an alternating current 206 on power line 208 (also referred herein simply as line 208), representative of a power line at a data center server or fault-critical location, a changing magnetic field is induced in magnetic core 202. This changing magnetic field induces a current 210 in coil 200. Buffer 204 amplifies the voltage difference between the two inputs to produce an output to processor 212 which receives the output 214 of buffer 204. In connection with a first threshold level being reached at output 214, processor 212 may make a determination as to whether current is being supplied to a server being powered by line 208.

With reference still to FIG. 1, antenna 216 may be also wrapped as a coil around magnetic core 202. Each end of antenna 216 feeds the input of an amplifier such as buffer 218. An alternating voltage on line 208 which in fact creates a changing electric field despite no substantial current (e.g, below the first threshold voltage) in line 208 induces a changing magnetic field in magnetic core 202. This changing magnetic field induces a current 215 in antenna 216. In connection with a second threshold level (distinguished from the first threshold level referenced above) being reached, at the output of buffer 218, which feeds an input to processor 212, a determination may be made as to whether an electric field is present near line 208 sufficient to indicate the presence of ac power to line 208 without the presence of substantial current being drawn on line 208 by a server (not shown).

Powerline 208 status reported to processor 212 may be communicated by transmitter 221 which may also serve as a transceiver (which may be implemented as separately as a transmitter and a receiver) for transmitting status, via antenna 223, to and/or receiving operational commands from a remote location. In connection with status conditions detected by processor 212, alerts may be transmitted by transmitter 221 through antenna 223 to a remote location such as a monitoring station which can dispatch service personnel to the facility being monitored.

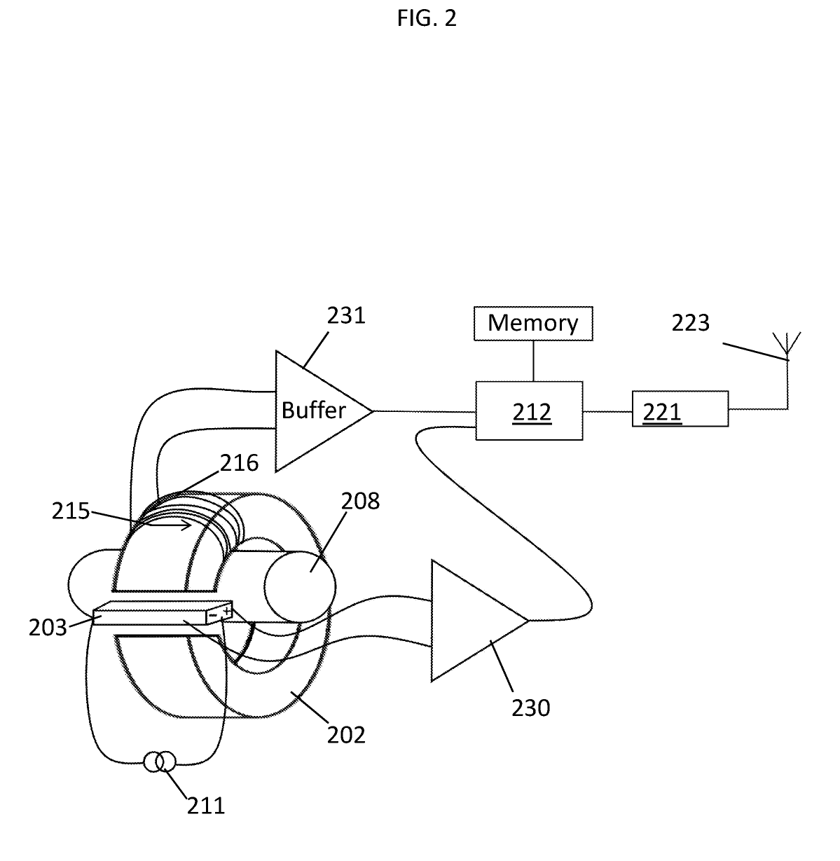

FIG. 2 illustrates a schematic/perspective drawing of another embodiment making use of an open loop current sensor which employs a Hall-effect sensor 203 positioned in the air gap of an open loop magnetic core 202. The Hall effect embodiments herein provide a more complicated sensor but with possibly a greater degree of current measurement capabilities. Magnetic core 202 alters the path of currents moving along the substrate of sensor 203 so as to deflect charge carriers of opposite polarity to the outer edges. Current source 211 creates a current through the substrate of sensor 203. Alternating current through line 208 changes the magnetic field of magnetic core 202 which induces a current on the substrate of the Hall-effect sensor 203. Buffer 230 amplifies the voltage difference between inputs received from either side of substrate of sensor 203 as shown. Buffer 230 may be biased accordingly with resistors of appropriate resistor values (not shown) to produce an output levels sufficient to distinguish between current being present or not present on line 208 at or above a particular threshold.

While current through line 208 may also produce an induced magnetic field causing another component of current through antenna 216, such will result in a greater magnitude of alternating current in antenna 216. Those levels of detection may be determined and distinguished by processor 212.

With reference still to FIG. 2, antenna 216 may be also wrapped as a coil around magnetic core 202. Each end of antenna 216 feeds the input of an amplifier such as buffer 231. An alternating voltage on line 208 which in fact creates a changing electric field despite no substantial current (e.g, below the first threshold voltage) in line 208 induces a changing magnetic field in magnetic core 202. This changing magnetic field induces a current 215 in antenna 216. In connection with a second threshold level (distinguished from the first threshold level referenced above) being reached, at the output of buffer 231, which feeds an input to processor 212, a determination may be made as to whether an electric field is present near line 208 sufficient to indicate the presence of ac power to line 208 without the presence of substantial current being drawn on line 208 by a server (not shown).

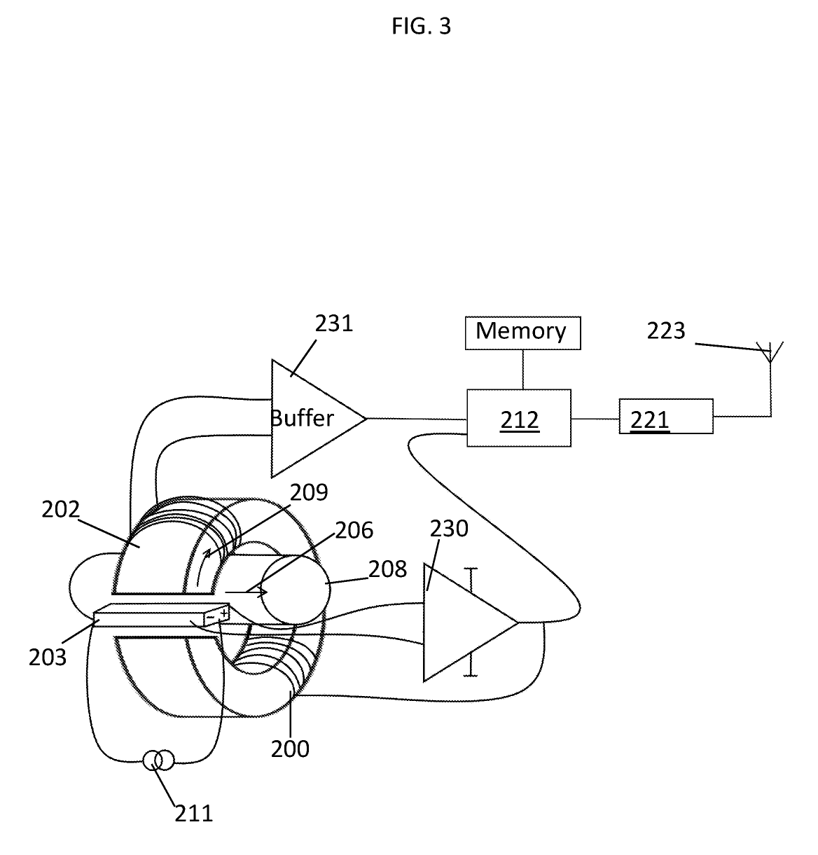

FIG. 3 illustrates a schematic/perspective drawing of another embodiment making use of closed loop current sensor which employs a Hall-effect sensor 203 positioned in the air gap of an open loop magnetic core 202. In addition, a compensation flux 209 is created in core 202 to counteract the flux created in line 208. The closed loop Hall-effect embodiment provides a compensation current in coil 200 resulting in a flux equal in amplitude, but opposite in direction, to the flux created by the current on line 208.

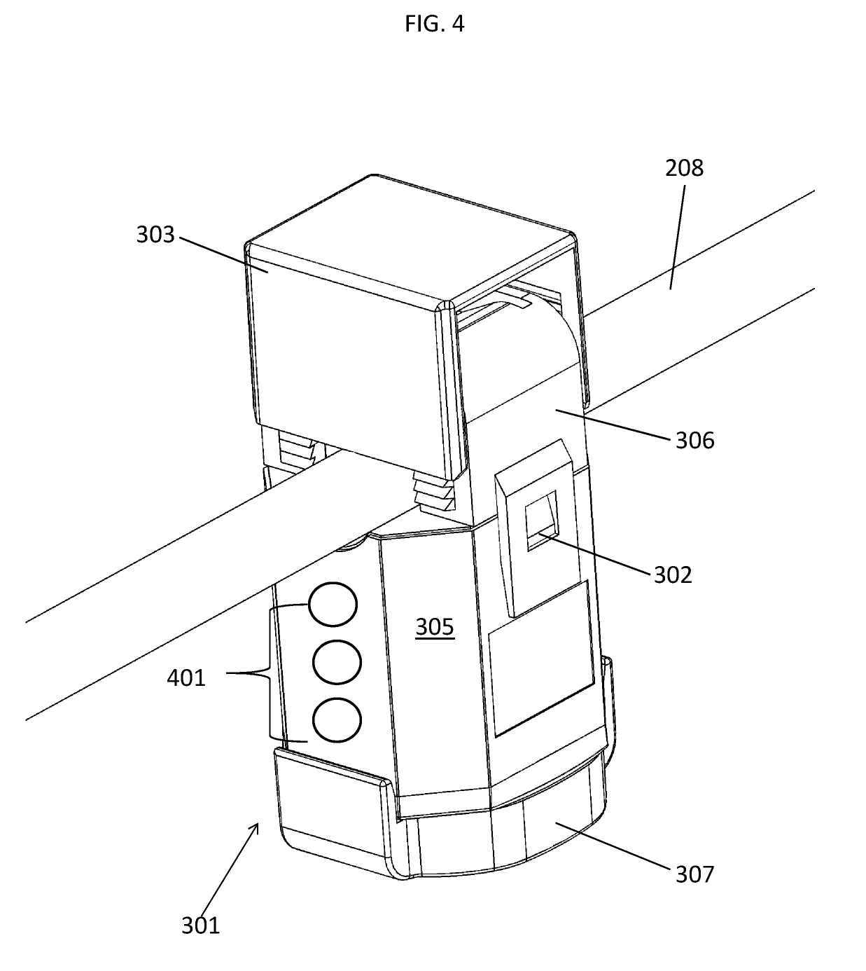

FIG. 4, illustrates an embodiment of the foregoing wherein an alternating current transducer 301 engages powerline 208. In the embodiment, the transducer 301 is configured to monitor both the current passing through the powerline 208 and electric field generated. In an embodiment, the alternating current transducer 301 is further configured to wirelessly transmit the electric field and current metrics to a monitoring system.

In an embodiment of the invention, the alternating current transducer 301 may be powered by the electromagnetic field generated by the powerline 208 via induction. In another embodiment, an internal power source or external power source provides the power source required to operate the alternating current transducer.

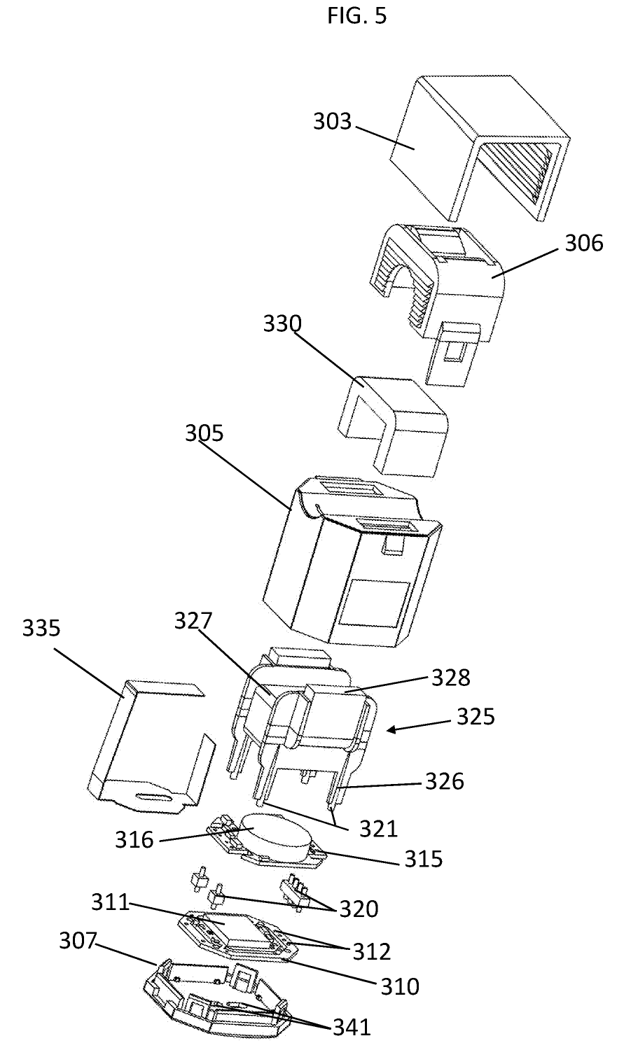

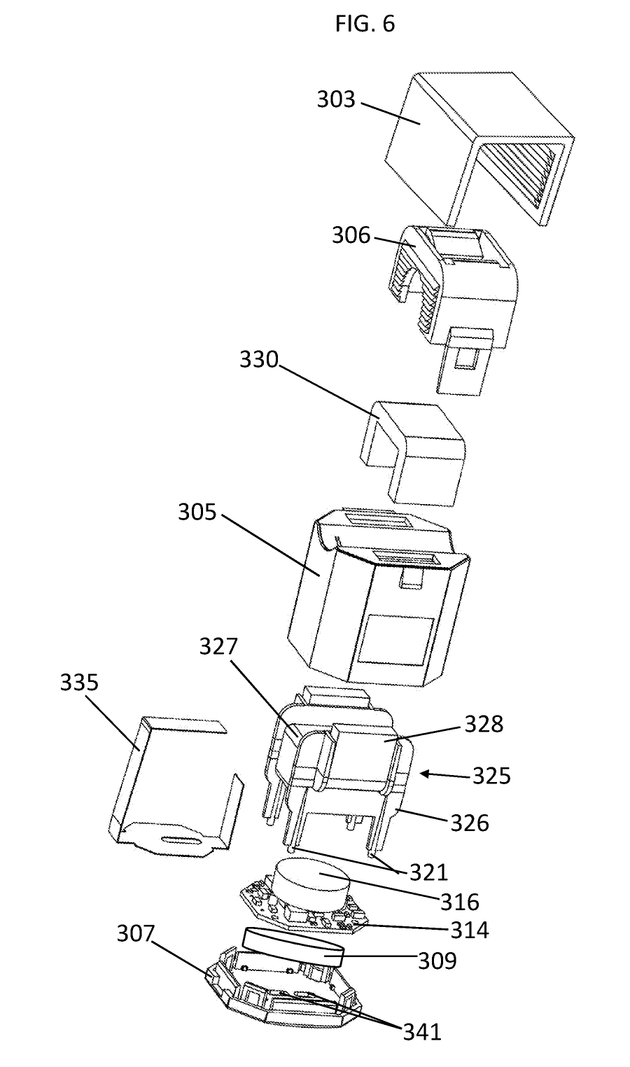

In an embodiment, the alternating current transducer 301 is clipped onto a powerline 208 by releasing a tab 302 such that the top part opens to allow the transducer to be removed from or attached to a powerline. In an embodiment, the enclosure further comprises a bottom lid (307 in FIGS. 5-6), provided to keep the internal components of the transducer contained. In an embodiment, the alternating current transducer can accommodate powerlines which vary in thickness. In another embodiment, the transducer can be attached to a powerline up to 50 mm in diameter.

In an embodiment, alternating current transducer 301 is further provided with ratcheting clip 303. The ratcheting clip retains the transducer in position and limits fluctuation in the monitored electric field caused by changes in distance between powerline 208 and a flexible antenna (335 in FIGS. 5-6) provided within transducer.

With reference to FIGS. 5-6, an exploded view of components of alternating current transducer 301 are shown apart from enclosure 305. The components of this embodiment include system-on-a chip (SOC) board 310, power supply board 315, connection headers 320, transformer 325, top conductive core 330, and flexible antenna 335.

With reference to FIG. 5, SOC board 310, power supply board 315, and connection headers 320 are shown. In this embodiment, SOC board 310 may be a printed circuit board (PCB) with a System on a Chip (SoC) 311 affixed thereto and connected to the PCB, the entirety of which comprises a networking module or portion thereof. SOC 311 may present multiple configurations appropriate for an alternating current transducer. Silicon Labs™ MGM111 networking module is one such SOC, configured with an internal antenna. In another embodiment, the networking module may be configured to connect to an external antenna. These networking modules include wireless communication capability to allow reporting back to a monitoring center for the data center or fault-critical location.

SOC board 310 may be provided with connection holes 312 on the PCB. The connection holes 312 are configured to accept headers 320. The arrangement provides for an easy connection to the power supply board 315. In an embodiment, the headers 320 may be soldered to the SOC board 310 and power supply board 315 to provide a more secure attachment and electrical connection. In other embodiments, electric communication between the SOC board 310 and power supply board 315 may be achieved by direct soldering, integration onto a single PCB, or by other appropriate means.

Power supply board 315 may be a PCB provided with energy management components and adapted to receive a super capacitor 316. With reference to FIG. 6, the SOC board and power supply may be provided on a single powered SOC board 314. In another embodiment, different energy storage units may be supplied, or a power may be provided by a power source external to the alternating current transducer. Further, a second power source may be provided as a backup. In the case where an external power source is used, one or more through-holes may be provided in the bottom lid 307 to allow a power source to connect to leads provided on SOC board 310 of FIG. 5 or powered SOC board 314 of FIG. 6.

FIG. 6 illustrates an embodiment wherein transformer 325 is provided with frame 326, wire windings 327 (which may be covered with tape), and bottom conductive core 328. Transformer 325 may be placed on powered SOC board 314, such that pegs 321 of frame 326 engage with corresponding apertures provided on SOC board 314. Frame 326 may be adhered to the SOC board 314 form by an interference fit, or it may be adhered in connection with a clearance fit.

With reference back to FIG. 5, an embodiment is depicted wherein SOC board 310 engages flexible antenna 335. In this embodiment, flexible antenna 335 makes electrical contact with SOC board 310 via wiring pads provided on SOC board 310 (not specifically shown). Flexible antenna 335 is used to monitor the electromagnetic field of a powerline, to which the alternating current transducer is electrically/magnetically engaged.

Flexible antenna 335 may be wrapped around transformer 325 and wire windings 327 (which may be covered with tape) of transformer 325. In a further embodiment, the flexible antenna 335 is attached to the windings 327 with tape, adhesive, or other suitable method of attachment.

The SOC herein may be configured to receive different forms of wireless communication, such as Bluetooth, Bluetooth LE, Zigbee, radio frequency, or other forms of wireless communication. These forms of communication may serve the transmitter 221 or a transceiver as discussed above. In some embodiments, the alternating current transducer is configured to the preferred form of wireless communication depending on the preferred communication of the monitoring system. In other embodiment, a hardwired connection may be used for communication with a monitoring system.

With reference to FIGS. 5 and 6, top conductive core 330 fits into the enclosure top 306. In some embodiments, top conductive core 330 is retained by plastic tabs (not shown) provided on the enclosure top 306. In other embodiments, conductive core 330 may be attached to enclosure top 306 by adhesion or other attachment means. In still other embodiments, top conductive core 330 is identical to bottom conductive core 328 of the transformer 325. Top core 330 and bottom conductive core 328 may vary in shape, size, and material as deemed appropriate. In example embodiments, the conductive core is comprised of ferrite, a magnetic material, hollow air core, air core or another material which is electrically and/or magnetically conductive. In another embodiment, a solid conductive core may be provided, wherein the core is not split into bottom and top portions. In such an embodiment, the transducer may be slid onto the end of a powerline, or the powerline may be spliced to place the transducer onto the line.

An antenna (such as an antenna on board 310 or 314 or internal to an SOC) is provided to transmit the status of the transducer to a monitoring system (not shown). Electric field status (present or not) and current levels, monitored by the transducer, are sampled by the monitoring system to allow the detection of faults. In an exemplary embodiment, if a monitoring system shows a sudden spike in current, followed by a loss in current and electric field, it is a good indication that there is a problem downstream, such as a tripped breaker or broken fuse. Should the monitoring system receive a signal from a transducer which shows no current, but an electric field is present, then there is a good indication that the problem is upstream of the transducer and a system may be idle.

In some embodiments, multiple transducers may be used along with a monitoring system to monitor large electrical systems which may be present in data centers, phone centers, or other applications wherein power supply is critical (herein referred to as fault-critical locations). When a fault is recorded, or detected anywhere in the system, the fault location is identified by the transducer at which it has occurred, and the type of fault, indicative of the problem, recorded is. Such allows for quickly locating and troubleshooting an electrical fault in a system of practically any size. Furthermore, the simplicity of the transducer unit makes it a cost effective solution for continuous monitoring of power supplies.

The transducer is provided as a portable unit to be attached to a powerline. In an embodiment, the transducer has box dimensions of approximately 4 (centimeters) by 2.5 cm by 2 cm. In another embodiment, the transducer has box dimensions of approximately 6 cm by 3.5 cm by 3 cm. In an embodiment, the box dimensions of the transducer may range from about 4-6 cm in height, 2-3 centimeters in length, and 2.5-3.5 centimeters in depth.

Enclosure 305 or SOC board 310 may be provided with one or more lights for indicating the status of powerline 208 and/or the status of transducer 301. Such lights 401 are shown on enclosure 305 in FIG. 4. As an example, implementation with three lights, for instance, a first light may indicate the presence of a current; a second light may indicate the presence of an electric field; and a third light may indicate the presence of both current and an electric field without requiring the other lights to be lit. Alternatively, no lights lit may be indicative of no power to transducer 301 or no power on line 208. In other embodiment, a single light (not shown) configured to emit multiple colors may be provided, and the color can be configured to indicate the presence of a current, electric field, or both. Multiple configurations of lights may be used for the same purpose of indicating presences of current, electric field, or faults. The lights may be also used to indicate the proper function of the transducer and or powerline, etc. The foregoing described visual light indication is intended to aid service personnel in readily determining the location of faults at a location such as a data center.

In other embodiments, lights may be provided at bottom lid 307 visible, to an observer, through two or more through-holes (341 in FIGS. 5-6). In another embodiment, bottom lid 307, enclosure 305, or both will be comprised of a translucent or transparent plastic, such that the lights are visible to an observer.

The foregoing may be powered parasitically through a powerline and it may be optionally provided back-up power through an additional battery (309 in FIG. 6). In connection with power no longer being sensed, failure to detect an alternating current or electric field, an alert may be transmitted to a remote location as powered by the available mechanism powering the transducer.

For embodiments including a transceiver or a receiver separate from a transmitter, instructions may be sent from a remote location to control the operations of concerning current sensing, electric field sensing, and reporting faults/sending alerts.

The invention has been described herein using specific embodiments for the purposes of illustration only. It will be readily apparent to one of ordinary skill in the art, however, that the principles of the invention can be embodied in other ways. Therefore, the invention should not be regarded as being limited in scope to the specific embodiments disclosed herein.

1. A fault detection transducer, for use in a data center, including a transducer for releasably clipping onto a powerline, the fault detection transducer comprising:
a transformer, for detecting a changing electric field, having
i. a top conductive core, a bottom conductive core configured with the top conductive core to admit a powerline circumference therebetween and
ii. one or more wire wrappings encircling the top and bottom conductive cores;
iii. a tab, connected to the transducer, configured to allow the release of the powerline from between the top and bottom conductive cores;
an enclosure top configured to secure the top conductive core;
a bottom lid spaced apart from the enclosure top; and
an enclosure, surrounding the bottom conductive core and interposed between the enclosure top and the bottom lid;
a first antenna for detecting an electromagnetic field; and
a system on a chip (SOC), including a networking module, in communication with the transformer and coupled to the first antenna, and further including a transmitter and a second antenna connected to the transmitter, the networking module being operable to cause the transmission of an alert status in connection with a failure to detect the changing electric field
d. a releasable tab on the enclosure for removing the transducer from the powerline; and
e. a ratcheting clip, configured to engage the enclosure top, for securing the transducer to the powerline.

2. The fault detection transducer of claim 1, further comprising a power supply, coupled to SOC.

3. The fault detection transducer of claim 2, wherein the power supply is a battery.

4. The fault detection transducer of claim 2, wherein the power supply is a super capacitor.

5. The fault detection transducer of claim 2, wherein the power supply is an external power source.

6. The fault detection transducer of claim 1, further comprising one or more indicator lights on the enclosure.

7. The fault detection transducer of claim 6, wherein a first indicator light of the one or more indicator lights illuminates when the electric current is detected in the powerline.

8. The fault detection transducer of claim 7, wherein a second indicator light of the one or more indicator lights illuminates when the electromagnetic field is detected in the powerline.

9. (canceled)

10. (canceled)

11. (canceled)

12. (canceled)

13. (canceled)

14. (canceled)

15. (canceled)

16. (canceled)

17. (canceled)

18. (canceled)

19. (canceled)

20. (canceled)

21. (canceled)
